(19) United States
(12) Patent Application Publication
(10) Pub. No.: US 2007/0200489 A1
(43) Pub. Date: Aug. 30, 2007

(54) Large area organic electronic devices and methods of fabricating the same

(76) Inventors: Hak Fei Poon, Niskayuna, NY (US); Svetlana Rogojevic, Niskayuna, NY (US); Dennis Coyle, Clifton Park, NY (US)

Correspondence Address: Patrick S. Yoder;FLETCHER YODER, P.O. Box 692289, Houston, TX, 77269-2289, US

(21) Appl. No.: 11/345,216

(22) Filed: Feb. 1, 2006

(51) Int. Cl. H01J 1/62

(52) U.S. Cl. 313/502

(57) ABSTRACT

A method of fabricating organic electronic devices is provided. More specifically, methods of fabricating organic electroluminescent devices having active polymer layers are disclosed. The active polymer layers are disposed by a web coating method such as Micro Gravure™ coating. The active polymer layers are patterned using a solvent assisted wiping process.

### BACKGROUND

Large area semiconductive organic-based devices for producing light from electrical energy (lighting sources) and devices for producing electrical energy from light (photovoltaic sources) may be used in a wide variety of applications. For instance, high efficiency lighting sources are continually being developed to compete with traditional area lighting sources, such as fluorescent lighting. While electroluminescent devices such as light emitting diodes have traditionally been implemented for indicator lighting and numerical displays, advances in light emitting diode technology have fueled interest in using such technology for area lighting. Light Emitting Diodes (LEDs) and Organic Light Emitting Diodes (OLEDs) are solid-state semiconductor devices that convert electrical energy into light. While LEDs implement inorganic semiconductor layers to convert electrical energy into light, OLEDs implement organic semiconductor layers to convert electrical energy into light. Generally, OLEDs are fabricated by disposing multiple layers of organic thin films between two conductors or electrodes. The electrode layers and the organic layers are generally disposed between two substrates. When electrical current is applied to the electrodes, light is produced. Unlike traditional LEDs, OLEDs can be processed using low cost, large area thin film deposition processes. OLED technology lends itself to the creation of ultra-thin lighting displays, as well as other large area applications. Significant developments have been made in providing general area lighting implementing OLEDs.

Photovoltaic (PV) devices may be fabricated using similar materials and concepts as the LED devices. Semiconductive PV devices are generally based on the separation of electron-hole pairs formed following the absorption of a photon from a light source, such as sunlight. An electric field is generally provided to facilitate the separation of the electrical charges. The electric field may arise from a Schottky contact where a built-in potential exists at a metal-semiconductor interface or from a p-n junction between p-type and n-type semiconducting materials. Such devices are commonly made from inorganic semiconductors, especially silicon, which can have monocrystalline, polycrystalline, or amorphous structure. Silicon is normally chosen because of its relatively high photon conversion efficiency. However, silicon technology has associated high costs and complex manufacturing processes, resulting in devices that are expensive in relation to the power they produce.

Like OLEDs, organic photovoltaic (OPV) devices, which are based on active semiconducting organic materials, have recently attracted more interest as a result of advances made in organic semiconducting materials and are being employed in large area applications on an increasing basis. These materials offer a promise of better efficiency that had not been achieved with earlier OPV devices. Typically, the active component of an OPV device comprises at least two layers of organic semiconducting materials disposed between two conductors or electrodes. At least one layer of organic semiconducting material is an electron acceptor, and at least one layer of organic material is an electron donor. An electron acceptor is a material that is capable of accepting electrons from another adjacent material due to a higher electron affinity of the electron acceptor. An electron donor is a material that is capable of accepting holes from an adjacent material due to a lower ionization potential of the electron donor. The absorption of photons in an organic photoconductive material results in the creation of bound electron-hole pairs, which must be dissociated before charge collection can take place. The separated electrons and holes travel through their respective acceptor (semiconducting material) to be collected at opposite electrodes.

While the particular layers of organic semiconducting materials that are implemented in PV devices, may differ from the particular layers of organic materials implemented in OLED devices, the similarity in structure between OPV devices and OLED devices provide similar design and fabrication challenges. In some instances, techniques implemented in fabricating OLED devices may also be implemented in fabricating OPV devices and vice versa. Accordingly, similar issues and challenges may arise in contemplating the fabrication of large area OLED devices and large area OPV devices.

One challenge with fabricating large area organic electronic devices such as OLEDs and OPVs is in disposing the active polymer layers. For instance, OLEDs generally include a light emitting layer, an electron transport layer and a hole transport layer arranged between two electrodes. Conventional ways of applying these organic electroluminescent layers over large areas are expensive due to high processing cost and process limitations. One common technique of disposing the active polymer layers is by spin coating, where liquid film is spread onto a rotating substrate at high speed. However, this approach is limited to small area coating due to size limitations of the spinning chamber. Further, spin coating is a batch operation. Over 99% of the coating solution may be wasted in the spin-coating process, leading to high material cost.

Another design challenge associated with the fabrication of large area organic electronic devices is in the patterning of the active polymer layers. As will be appreciated, in order to conform to device design specifications and maximize the device yield, the organic layers, including the active polymer layers, are often patterned to various textures, topographies and geometries. The patterning of the active polymer layers has been conventionally performed using laser ablation, where a patterned photomask covers the area to be patterned while the remaining area is selectively etched using a laser beam. One problem associated with such patterning of the active layers in organic electronic devices is that the process is not compatible with plastic substrates. The laser beam generates substantial local heating which can damage the substrate due to the large mismatch between the thermal expansion coefficients of the electrode material and the plastic substrate underneath. In addition, the process is extremely slow, expensive and cannot be easily performed on large specimens or in fieldwork.

Accordingly, there is a need for improved deposition and patterning techniques in the fabrication of large area organic electronic devices.

### BRIEF DESCRIPTION

In accordance with exemplary embodiments of the present invention, there is provided a method of fabricating an organic electronic device comprising disposing a first active polymer layer onto a first electrode by a web coating process. The method further comprises disposing a second active polymer layer onto the first active polymer layer by the web coating process. The method further comprises patterning at least one of the first and second active polymer layers by solvent assisted wiping.

In accordance with another exemplary embodiment of the present invention, there is provided a method of fabricating a large area array of organic electronic devices comprising disposing a conductive layer onto a flexible substrate. The method further comprises patterning the conductive layer to form a plurality of electrically isolated conductive regions. The method further comprises disposing a first active polymer layer onto the conductive layer by a web coating process, such that the entire conductive layer is covered by the first active polymer layer. The method further comprises patterning the first active polymer layer to form a plurality of isolated first active polymer regions, wherein each of the plurality of isolated first active polymer regions is patterned to cover at least a portion of a respective one of the plurality of electrically isolated conductive regions, wherein the patterning is done by solvent assisted wiping.

In accordance with still another exemplary embodiment of the present invention, there is provided a method of fabricating an organic light emitting diode system comprising disposing a hole transport layer onto a flexible substrate having a plurality of first electrodes patterned thereon, wherein the hole transport layer is disposed using a web coating process. The method further comprises patterning the hole transport layer by solvent assisted wiping. The method further comprises disposing a light emitting polymer layer onto the hole transport layer using the web coating process. The method further comprises patterning the light emitting polymer layer by solvent assisted wiping.

### DRAWINGS

These and other features, aspects, and advantages of the present invention will become better understood when the following detailed description is read with reference to the accompanying drawings in which like characters represent like parts throughout the drawings, wherein:

FIG. 1 is a top view of an exemplary array of organic electronic devices which may be fabricated in accordance with embodiments of the present invention;

FIG. 2 is a cross-sectional view of an exemplary organic electronic device of FIG. 1 which may be fabricated in accordance with embodiments of the present invention;

FIG. 3 is a simplified diagrammatic view of a system for disposing the active polymer layers of the organic electronic devices of FIGS. 1 and 2 in accordance with embodiments of the present invention;

FIG. 4 is a cross-sectional view of a number of the organic electronic devices of FIG. 1 which may be fabricated in accordance with embodiments of the present invention; and

FIG. 5 is a flow chart of an exemplary process for fabricating organic electronic devices in accordance exemplary embodiments of the present invention.

### DETAILED DESCRIPTION

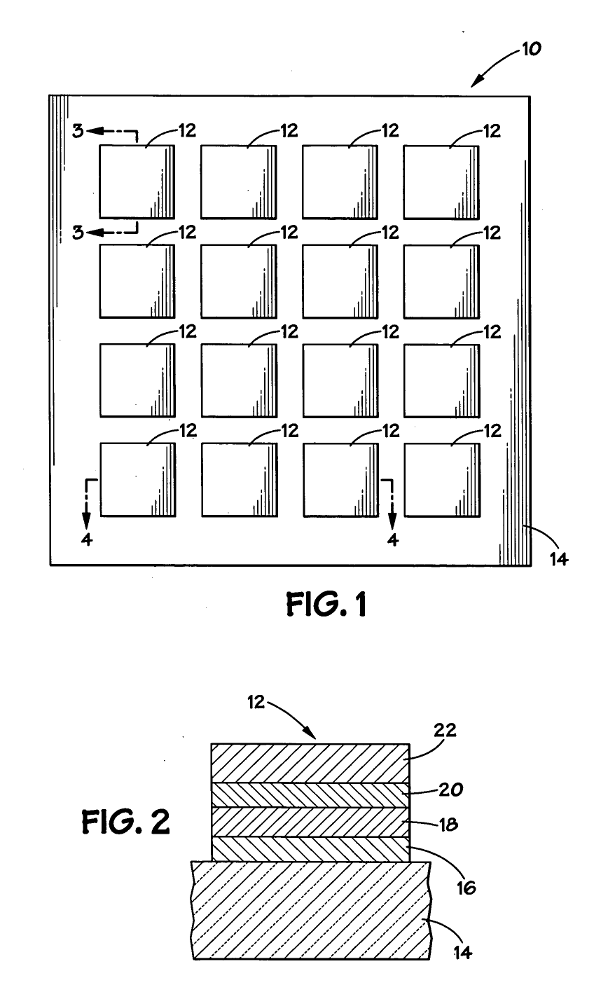

Referring initially to FIG. 1, an exemplary array 10 of organic devices 12 is illustrated. The array 10 may include any number of organic devices 12. Further, the array 10 may be configured for use as a large area array of organic devices 12, as will be described further below. As used herein, “adapted to,” “configured to,” and the like refer to elements that are sized, arranged or manufactured to form a specified structure or to achieve a specified result. The organic devices 12 may be organic photo voltaic devices (OPVs) or organic light emitting diodes (OLEDs), for example. As described above, the fabrication of organic devices may be similar, regardless of device type. As will be appreciated, the specific material layers and interconnection of the electrodes may vary but the deposition and patterning of the layers may employ similar techniques.

Each of the organic devices 12 of the array 10 may be fabricated on a film or sheet of flexible, transparent material. The flexible transparent material may be configured to form a substrate 14 for the array 10. The flexible substrate 14 may comprise any suitable material, such as polyethylene terepthalate (PET), polycarbonate (e.g., LEXAN), polymer material (e.g., MYLAR), polyester, or metal foil, for example. In some embodiments, the substrate 14 comprises any material having a high melting point, thereby allowing for high processing temperatures (e.g., >200° C.). Further, the substrate 14 may be advantageously transparent and has a high rate of transmission of visible light (e.g., >85% transmission). Further, the substrate 14 may advantageously comprise a material having a high impact strength, flame retardancy and thermoformability, for example.

In one exemplary embodiment, the substrate 14 may have a length of approximately 4 feet and a width of approximately 1 foot, for example. As can be appreciated, other desirable dimensions of the substrate 14 may be employed. The substrate 14 may have a thickness in the range of approximately 1-125 mils. As can be appreciated, a material having a thickness of less than 10 mils may generally be referred to as a “film” while a material having a thickness of greater than 10 mils may generally be referred to as a “sheet.” It should be understood that the substrate 14 may comprise a film or a sheet. Further, while the terms may connote particular thicknesses, the terms may be used interchangeably, herein. Accordingly, the use of either term herein is not meant to limit the thickness of the respective material, but rather, is provided for simplicity. Generally speaking, a thinner substrate 14 may provide a lighter and less expensive material. However, a thicker substrate 14 may provide more rigidity and thus structural support for the large area organic device. Accordingly, the thickness of the substrate 14 may depend on the particular application.

Advantageously, in accordance with embodiments of the present invention, the substrate 14 is flexible and may be dispensed from a roll, for example. Advantageously, implementing a roll for the substrate 14 enables the use of high-volume, low cost, reel-to-reel processing and fabrication of the active portion. The roll may have a width of 1 foot, for example. The substrate 14 may also be cut to a length desired for a particular application.

As can be appreciated by those skilled in the art, for large area applications, the organic electronic devices 12 are arranged to form a pattern or array. That is, the array is patterned or “pixelated” to provide a dense layer of discrete, electrically isolated patches or “pixels.” By pixelating one or more layers of each discrete device 12, shorting between the top and bottom electrodes will only effect the pixels that are shorted, rather than shorting the entire array. These techniques are well known to mitigate complete failure of the organic electronic devices and will be described further below.

Referring now to FIG. 2, a simplified cross-sectional view of an organic electronic device 12, taken along the cut-lines 2-2 of FIG. 1 is illustrated. The organic electronic device 12 of FIG. 2 may be representative of a single pixel of the array 10, for instance. In the present exemplary embodiment, the organic electronic device comprises and OLED. As previously described, the organic electronic device 12 (OLED) includes a substrate 14, a first electrode 16, active polymer layers 18 and 20, and a second electrode 22. The first electrode 16 may be configured to form the anode of the OLED and may comprise a transparent conductive oxide (TCO), such as indium-tin-oxide (ITO), for example. The transparent ITO may be disposed on the flexible transparent substrate 14 using roll-to-roll processing techniques. For instance, the first electrode 16 may be disposed by sputtering techniques to achieve a thickness in the range of approximately 50-250 nanometers, for example. The first electrode 16 preferably has a light transmission ratio of at least 0.8.

The second electrode 22 is configured to form the cathode. The second electrode 22 may comprise an aluminum film with a cathode activator NaF, for instance. Alternatively, the second electrode 22 may comprise calcium, magnesium or silver, for example. As with the first electrode 16, the second electrode 22 may be disposed using sputtering techniques to achieve a thickness in the range of 50-250 nanometers, for example. For bottom-emitting OLED devices, the second electrode 22 is advantageously reflective to reflect impinging light toward the front of the device where it can be coupled to the ambient environment. As will be appreciated, when a voltage potential is produced across the first electrode 16 and the second electrode 22, light is emitted from the active polymer layers 18 and 20. Alternatively, both electrodes may be transparent, to enable a transparent light-emitting device, or the bottom electrode may be reflective, and the top electrode transparent, in the case of a top-emitting OLED.

As previously described, a number of active polymer layers may be disposed between the first electrode 16 and the second electrode 22. As can be appreciated, for an OLED device, the active polymer layers may comprise several layers of organic light-emitting polymers, such as a polyphenylene vinylene or a polyfluorene, typically from a xylene solution. The number of layers and the type of organic polymers disposed will vary depending on the application, as can be appreciated by those skilled in the art. In one exemplary embodiment of an OLED device, the active polymer layer 20 may comprise a light emitting polymer (LEP) such as polyfluorene, and the active polymer layer 18 may comprise a hole transport layer such as poly(3,4)-ethylendioxythiophene/polystyrene sulfonate (PEDOT/PSS). As will be appreciated, other light emitting polymers and hole transport or electron transport layers may be employed. Further, additional active polymer layers may be employed in the OLED device.

If the organic electronic device 12 is an OPV device, the types of organic materials used for the active polymer layers 18 and 20 may be different from those described above with reference to the OLED devices. An organic PV device comprises one or more layers that enhance the transport of charges to the electrodes, as described above. For example, in an OPV device, the active polymer layers 18 and 20 may include an electron donor material and an electron acceptor material. The electron donor layer may comprise metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium, dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly(phenylene vinylene), poly(thienylene vinylene), poly(isothianaphthalene); and poly(silane), for instance. Further, the electron donor material may also include a hole transport material, such as triaryldiamine, tetraphenyldiamine, aromatic tertiary amines, hydrazone derivatives, carbazole derivatives, triazole derivatives, imidazole derivatives, oxadiazole derivatives having an amino group, and polythiophene, for instance.

The electron acceptor material in an OPV device may include perylene tetracarboxidiimide, perylene tetracarboxidiimidazole, anthtraquinone acridone pigment, polycyclic quinone, naphthalene tetracarboxidiimidazole, CN- and CF₃-substituted poly(phenylene vinylene), and Buckminsterfullerene, for instance. Further, the electron acceptor material may also include an electron transport material, such as metal organic complexes of 8-hydroxyquinoline; stilbene derivatives; anthracene derivatives; perylene derivatives; metal thioxinoid compounds; oxadiazole derivatives and metal chelates; pyridine derivatives; pyrimidine derivatives; quinoline derivatives; quinoxaline derivatives; diphenylquinone derivatives; nitro-substituted fluorine derivatives; and triazines, for example.

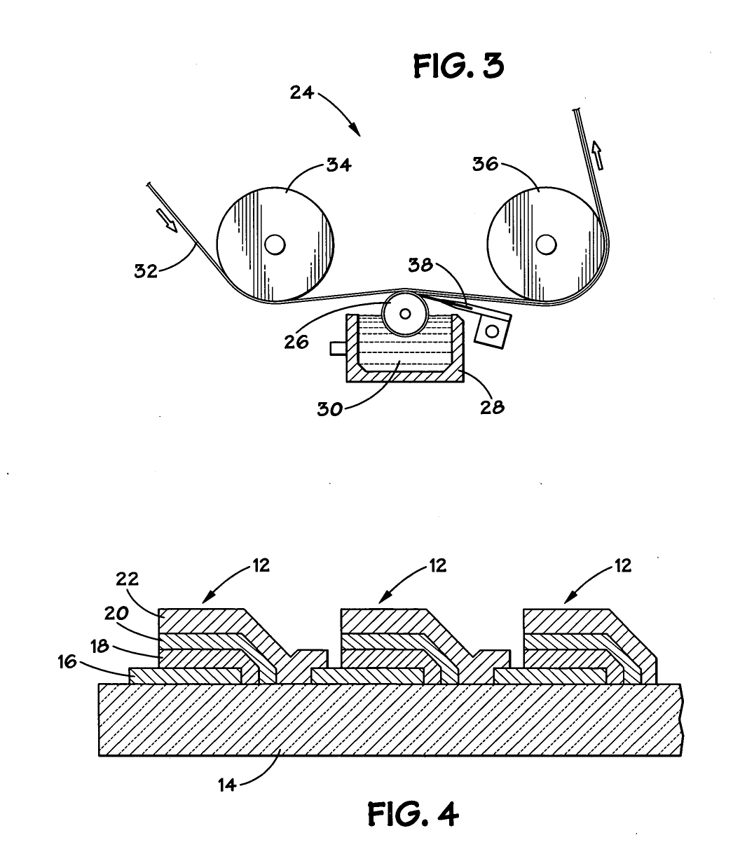

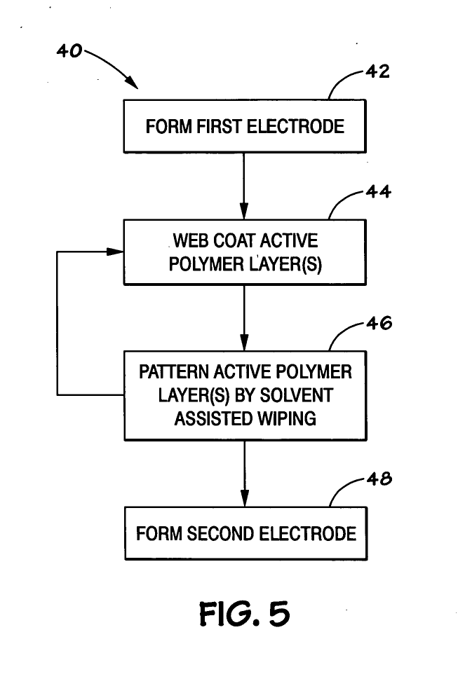

As previously described, the flexible substrate 14 is advantageously compatible with reel-to-reel processing. Accordingly, the deposition and patterning of the active polymer layers 18 and 20 may be more difficult than in conventional, small-area indicator lighting OLEDs or small OPV devices, for example. It should be understood that to apply the various layers that constitute the active polymer layers 18 and 20 and to pattern those layers, a number of coating steps may be implemented. Accordingly, further discussion regarding deposition and patterning of the active polymer layers 18 and 20 generally refers to a number of iterative coating steps, as will be described generally with reference to FIG. 5, and more specifically with regard to the EXAMPLE. In accordance with embodiments of the present invention, each of the active polymer layers 18 and 20 is disposed by a web-coating technique, such as Micro Gravure™ by Yasui Seiki Company. In accordance with further embodiments of the present invention, each of the active polymer layers 18 and 20 is patterned using a solvent assisted wiping (SAW) technique. The deposition and patterning techniques will be described further below with reference to FIGS. 3 and 4.

In accordance with embodiments of the present invention, the deposition of the active polymer layers 18 and 20 is achieved through any suitable web coating technique. Advantageously, web coating techniques generally result in less material waste than other deposition techniques. Web coating techniques may be employed with roll-to-roll fabrication systems. Still further, web coating techniques are easily employed in the fabrication of large area devices, such as large area OLEDs and OPVs.

One exemplary web coating technique for disposing the active polymer layers 18 and 20 is Micro Gravure™ coating which employs a system available by the Yasui Seiki Company. Micro Gravure™ coating is a continuous coating process specially adapted to apply a thin uniform layer of low-viscosity liquids. An exemplary Micro Gravure™ coating system 24 is illustrated in FIG. 3. An engraved roll (“gravure roll”) 26 having a small diameter and engraved with patterns, cells or grooves is provided. The surface of the gravure roll 26 is coated with a number of regularly spaced “cells” which determine a finite volume of internal capacity. The geometry, number and spacing, depth or other features of the cells can be varied to produce a range of total volume to accomplish coating weight (thickness) control. The Micro Gravure™ roll is mounted in bearings and rotates partially submerged in a coating pan 28. The coating pan 28 is filled with a liquid 30 which is to be applied to a web 32. As will be appreciated, in accordance with embodiments of the present invention, the liquid 30 may comprise an active polymer material such as an LEP or PEDOT layer, and the web 32 may comprise a flexible substrate material. More specifically, the web 32 may comprise the flexible substrate 14 coated with ITO to form the first electrode 16. The liquid 30 may comprise a material disposed on the ITO-coated flexible substrate 14 to form the first active polymer layer 18, which may be a PEDOT layer, for example. The same process may be employed to dispose the second active polymer layer 20, which may be an LEP layer, for example, on top of the first active polymer layer 18.

During fabrication, the gravure roll 26 is dipped in the liquid 30 and the web 32 is guided over the gravure roll 26 by rollers 34 and 36. The rollers 34 and 36 are configured to guide the roll 30 over and in contact with the gravure roll 26. When the web 32 reaches the gravure roll 26 which is coated with the liquid 30, the cells or grooves in the surface of the gravure roll 26 are filled. Rotation of the gravure roll 26 picks up the liquid 30, which is doctored (pre-metered) by a flexible steel blade 38 as the gravure roll 26 rotates toward the contact point of the web 32. Excess liquid may be scraped from the surface of the gravure roll 26 by the blade 38. The gravure roll 26 is reverse-wiped across a moving tensioned reel-to-reel surface, such as the substrate 14 having the ITO layer 16 disposed thereon, to transfer a fraction of the liquid contained in the engraved surface of the gravure roll 26 onto the surface. Because Micro Gravure™ coating is a continuous coating technique, the disposed layer may be subsequently patterned, as will be described further below.

As will be appreciated, other web coating techniques may be employed to dispose the active polymer layers 18 and 20, in accordance with embodiments of the present invention. For instance, forward or reverse roll coating, direct forward gravure coating, offset gravure, flexographic printing, screen printing or inkjet printing may be employed to dispose the individual active polymer layers 18 and 20. Flexographic printing is a process wherein the area to be printed is raised on a flexible plate attached to a roll. Coating is transferred to the raised image from an engraved roll, after which the coating is transferred to the surface. Rotary screen printing uses a squeegee to push coating through open areas of a fine fabric mesh onto the substrate. Inkjet printing starts with drop formation at the nozzle of an inkjet device. The drop is dispensed onto the surface and inertial force and surface tension causes the drop to spread as it hits the surface.

As will be appreciated, once an active polymer layer 18 or 20 is disposed, it may be patterned to form isolated structures or pixels of the array 10 as illustrated in FIG. 1. In accordance with embodiments of the present invention, a solvent assisted wiping (SAW) technique may be implemented to pattern the active polymer layers 18 and 20. As will be appreciated, SAW techniques facilitate the removal of material over a selected area by solvating a portion of the material, such as a portion of the active polymer layers 18 and 20 by at least one of water, methanol, ethanol, isopropanol, acetone, toluene, xylene, or combinations thereof. The surface of the solvated portion of active polymer layer 18 or 20 is then wiped by a wiping head to remove a portion of the active polymer layer 18 or 20, or both, thereby patterning the layers. As will be described further below, in certain embodiments of the present invention, the active polymer layer 18 is disposed and patterned before the active polymer layer 20 is disposed and patterned. Alternatively, the active polymer layers 18 and 20 may be disposed and subsequently patterned simultaneously. The wiping head generally comprises at least one of a sponge, elastomer, thermoplastic, thermoset, fiber mat, porous material, polyurethane rubber, synthetic rubber, natural rubber, silicones, polydimethylsiloxane (PDMS), textured materials, and combinations thereof. Further, the wiping head may have any desirable profile to achieve the desired patterning of the underlying layer.

In one embodiment of the invention, the solvating species are selected for removing a single active polymer layer 18 or 20 with each wiping action without damaging underlying layers. In this exemplary embodiment, the active polymer layer 18 may be disposed and then patterned. Next, the active polymer layer 20 may be disposed and then patterned. The solvent used to pattern each layer will be different depending on the material of the layer being patterned. For example, an LEP layer in a two-layer structure can be patterned using xylene as a solvent without damaging a PEDOT layer underneath.

In another embodiment, the solvating species are selected to facilitate removal of multiple active polymer layers 18 or 20 with each wiping. That is, both active polymer layers 18 and 20 may be disposed and then both active polymer layers 18 and 20 may be patterned simultaneously. In typical instances, the active polymer layer 18 comprises a conductive polymer coating, such as PEDOT, which is very polar and dissolves only in hydrogen-bonding solvents like water. The active polymer layer 20 may comprise an LEP material that is non-polar, which dissolves only in non-polar solvents such as toluene or xylene. In order to remove multiple polymer coatings having extremely divergent solubility characteristics in a single wipe, suitable solvents for each polymer are dispersed in a third solvent to produce a homogeneous solution. The third, or dispersing, solvent is selected from a number of solvents, such as, but not limited to, alcohols (such as isopropanol, ethanol, methanol, and the like), ketones (such as acetone, methyl ethyl ketone, and the like), acetates, ethers, methylene chloride, or any solvent having intermediate solubility parameters. In this embodiment, two active polymer layers 18 and 20 can also be removed in one step with a solvent system containing water and xylene. In this particular embodiment, isopropanol is used to facilitate mixing of water and xylene to yield a homogeneous solution.

As previously described, in order to form an array 10 of organic electronic devices 12 (FIG. 1), the various layers are disposed and patterned to provide proper electrical paths. In one exemplary embodiment, adjacent devices 12 in a single row are connected in series to provide a short-tolerant design structure. FIG. 4 illustrates an exemplary design of three organic electronic devices 12 which are electrically connected in series. FIG. 4 is a cross-sectional view of three devices 12 taken across the cross-sectional lines 4-4 of FIG. 1. As will be appreciated, the embodiment illustrated in FIG. 4 is simply provided by way of example. Other configurations may be employed.

Specifically, FIG. 4 illustrates three organic electronic devices 12, coupled in series. The first electrode 16 may be disposed and patterned to form the isolated structures illustrated in FIG. 4. As described above, and described further below, each of the overlying layers, such as the active polymer layers 18 and 20 and the second electrode 22 may be disposed and patterned, as illustrated. In the exemplary embodiment of FIG. 4, each second electrode 22 is disposed and patterned to provide an electrically conductive path to the first electrode 16 an adjacent device in a single row of the array. As will be appreciated, by providing series connections for each of the adjacent devices in single row, a structure tolerant to electrical shorts (short-tolerant structure) is provided.

In accordance with embodiments of the present technique, fabrication of organic electronic devices are simplified by employing a web coating technique to dispose the active polymer layers 18 and 20 and a solvent assisted wiping (SAW) technique for patterning the active polymer layers 18 and 20. As will be appreciated, the precise steps for fabricating an organic electronic device in accordance with embodiments of the present invention will vary depending on the particular device being fabricated, the desired structure of the array, and the types of materials being deposited. However, those skilled in the art will appreciate the variations in the disclosed process. A number of baking and treatment steps may also be employed. The baking and treatment steps will vary depending on the materials deposited, the thickness of the materials, the type of underlying materials employed and other design variables that will be appreciated by those skilled in the art.

Referring now to FIG. 5, a flow chart illustrating a simplified process 40 for manufacturing an array of organic electronic devices in accordance with embodiments of the present invention is provided. First, a first electrode is formed, as indicated by block 42. The first electrode may comprise an ITO layer which is disposed on a flexible substrate and patterned to form a number of isolated ITO patterns. Next, a first active polymer layer is disposed on the ITO layer, as indicated by block 44. The first active polymer layer is disposed using a web coating technique such as Micro Gravure™ coating, for instance. The first active polymer layer may comprise a PEDOT layer, for example. Next, the PEDOT layer is patterned by solvent assisted wiping (SAW), as indicated in block 46. The PEDOT layer may be patterned, as illustrated in FIG. 4, for example. The deposition and patterning of the active polymer layers may be repeated, depending on the specific device being fabricated. In one exemplary embodiment, an LEP layer is disposed on the PEDOT layer using a web coating technique such as Micro Gravure™ coating. The LEP layer may then be patterned by a SAW technique to form the structure illustrated in FIG. 4. Alternatively, each of the PEDOT layer and the LEP layer may be disposed, before either layer is patterned (block 44). Once both layers have been disposed, the layers may be simultaneously patterned by a SAW technique (block 46). Finally, the second electrode may be disposed and patterned, as indicated by block 48. The second electrode may comprise aluminum, for example.

Without further elaboration, it is believed that one skilled in the art can, using the description herein, utilize the present invention to its fullest extent. The following example of a fabrication process is included to provide additional guidance to those skilled in the art in practicing the claimed invention. The example provided are merely representative of the work that contributes to the teaching of the present application. Accordingly, this example is not intended to limit the invention, as defined in the appended claims, in any manner.

### EXAMPLE

In the demonstrated example described herein, a roll of flexible ITO-coated PET (4″ wide web) was provided with a nominal sheet resistance of approximately 40 ohm/square. A portion of ITO coated PET (4×6 um) was first cut out and pre-cleaned. The portion was then treated with UV/Ozone for 10 minutes before coating to enhance the surface wettability. The web coating techniques exploited in the present example were by a Micro Gravure™ coating technique, as described above. Thus, after cleaning, the cleaned ITO coated PET was then stitched onto the web in the Micro Gravure™ coater. It will be appreciated that the cutting and stitching can be simplified when the substrate pretreatment module is integrated in the fabrication line. That is, the ITO coated flexible substrate may itself be the web, and thus, may be fed directly into the Micro Gravure™ coater.

Next the hole transport layer (0.75% PEDOT solution, from Baytron) was applied to the ITO substrate by Micro Gravure™ coating. The PEDOT solution had a solid concentration of 0.75% by weight and ˜20% of isopropanol. The solution was pre-filtered through a 0.45 um filter and de-gassed for 5 minutes under vacuum. The solution was then transferred to the coating pan in the Micro Gravure™ coater. The gravure roll contained a tri-helical engraving and was rotated in a reverse direction to the web motion. As a result, films, such as the PEDOT, may be applied to the ITO/PET substrate by shear forces. As will be appreciated, several factors affect the film thickness and uniformity. For instance, the speed ratio between the web and the gravure roll, coating solution concentration, cell volume of the Tri-helical engraving, web tension, doctor blade pressure, and distance between the web and the engraved roll all affect the film thickness and uniformity. For the present example, employing a 0.75% PEDOT solution, the web was run at about 1-2 m/min with the speed ratio between the engraved roll and the web maintained in the range of about 1 to about 1.5. After the PEDOT film was deposited on the ITO coated web, the coated PEDOT film was dried in a drying chamber at approximately 30° C. As will be appreciated, higher temperatures may be used to accelerate the drying process. The stitched ITO coated with PEDOT was then removed from the web and baked offline in an oven at 110° C. for 10 minutes. The final thickness of the dried PEDOT film was approximately 80 nm with a thickness variation of less than 10 nm.

After baking, the baked PEDOT coated film was then stitched back onto the web. Both the gravure roll and fluid container were cleaned and replaced with a light emitting polymer solution. In the present example, a polyfluorene, ADS329BE supplied by American Dye Source, Inc. was employed. The same coating procedure described above with regard to the PEDOT coating was repeated for the deposition of the light emitting polymer coating. With 1% LEP solution at a web speed of 1 m/min, a uniform film with a thickness of approximately 100 nm was obtained with no visible defects or thickness variation.

After the uniform PEDOT and LEP layers were deposited, the coated sample was then transferred to a solvent assisted wiping (SAW) module where the coating was selectively solvated and removed by a compliant head with a micro-textured surface. In the present example, the device was patterned according to a short tolerant design described above with reference to FIG. 4. In the present example, the PEDOT and LEP layers were both disposed and then the layers were patterned together, as discussed above. Alternatively, each layer may be patterned after deposition and before the deposition of the next layer. Once the PEDOT and LEP layers were patterned, the device was then removed from the web and baked at 110° C. for 10 minutes. Next a conventional cathode deposition encapsulation procedure was employed for deposition of the second electrode.

As described above, techniques for fabricating a large area organic electronic device is provided. Advantageously, the active polymer layers, such as the PEDOT and LEP layers are disposed using a web coating process, such as Micro Gravure™ coating, which allows for fabrication by roll-to-roll processing. Further, the active polymer layers may be patterned by solvent assisted wiping. Web coating allows for thicknesses of the active polymer layers in the range of approximately 0.01 μm-1 μm with a thickness variation of less than approximately 10%. The SAW technique allows for a feature size of the solvent assisted wiping patterns in range from about 10 μm to about 10000 μm.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

1. A method of fabricating an organic electronic device comprising:
disposing a first active polymer layer onto a first electrode by a web coating process;
disposing a second active polymer layer onto the first active polymer layer by the web coating process; and
patterning at least one of the first and second active polymer layers by solvent assisted wiping.

2. The method of fabricating an organic electronic device, as set forth in claim 1, wherein disposing the first active polymer layer onto the first electrode comprises disposing the first active polymer layer onto flexible substrate coated with indium tin oxide.

3. The method of fabricating an organic electronic device, as set forth in claim 1, wherein disposing the first active polymer layer onto the first electrode comprises disposing the first active polymer layer by Micro Gravure™ coating.

4. The method of fabricating an organic electronic device, as set forth in claim 1, wherein disposing the first active polymer layer onto the first electrode comprises disposing a hole transport layer onto the first electrode.

5. The method of fabricating an organic electronic device, as set forth in claim 1, wherein disposing the first active polymer layer onto the first electrode comprises disposing a PEDOT layer onto the first electrode.

6. The method of fabricating an organic electronic device, as set forth in claim 1, wherein disposing the second active polymer layer comprises disposing a light emitting polymer layer.

7. The method of fabricating an organic electronic device, as set forth in claim 1, wherein disposing the first active polymer layer comprises disposing the first active polymer layer having a thickness in the range of approximately 0.01 μm to 1.0 μm.

8. The method of fabricating an organic electronic device, as set forth in claim 1, wherein disposing the second active polymer layer comprises disposing the second active polymer layer having a thickness in the range of approximately 0.01 μm to 1.0 μm.

9. The method of fabricating an organic electronic device, as set forth in claim 1, wherein patterning comprises patterning the first active polymer layer before the second active polymer layer is disposed.

10. The method of fabricating an organic electronic device, as set forth in claim 1, wherein patterning comprises patterning the first active polymer layer and the second active polymer layer simultaneously.

11. A method of fabricating a large area array of organic electronic devices comprising:
disposing a conductive layer onto a flexible substrate;
patterning the conductive layer to form a plurality of electrically isolated conductive regions;
disposing a first active polymer layer onto the conductive layer by a web coating process, such that the entire conductive layer is covered by the first active polymer layer; and
patterning the first active polymer layer to form a plurality of isolated first active polymer regions, wherein each of the plurality of isolated first active polymer regions is patterned to cover at least a portion of a respective one of the plurality of electrically isolated conductive regions, wherein the patterning is done by solvent assisted wiping.

12. The method of fabricating a large area array of organic electronic devices, as set forth in claim 11, wherein disposing the conductive layer onto the flexible substrate comprises disposing the conductive layer onto a portion of a roll of flexible material.

13. The method of fabricating a large area array of organic electronic devices, as set forth in claim 11, wherein disposing the first active polymer layer onto the conductive layer by a web coating process comprises disposing the first active polymer layer by Micro Gravure™ coating.

14. The method of fabricating a large area array of organic electronic devices, as set forth in claim 11, wherein disposing the first active polymer layer comprises disposing a hole transport layer.

15. The method of fabricating a large area array of organic electronic devices, as set forth in claim 11, wherein disposing the first active polymer layer comprises disposing a PEDOT layer.

16. The method of fabricating a large area array of organic electronic devices, as set forth in claim 11, further comprising:
disposing a second active polymer layer onto the first active polymer layer by a web coating process, such that the entire first active polymer layer is covered by the second active polymer layer; and
patterning the second active polymer layer to form a plurality of isolated second active polymer regions, wherein each of the plurality of isolated second active polymer regions is patterned to cover at least a portion of a respective one of the plurality of isolated first active polymer regions, wherein the patterning is done by solvent assisted wiping.

17. The method of fabricating a large area array of organic electronic devices, as set forth in claim 16, wherein disposing the second active polymer layer comprises disposing the second active polymer layer by Micro Gravure™ coating.

18. The method of fabricating a large area array of organic electronic devices, as set forth in claim 16, wherein disposing the second active polymer layer comprises disposing a light emitting polymer layer.

19. The method of fabricating a large area array of organic electronic devices, as set forth in claim 16, comprising disposing a second conductive layer onto the second active polymer layer.

20. The method of fabricating a large area array of organic electronic devices, as set forth in claim 16, wherein patterning the first active polymer layer and patterning the second active polymer layer occur simultaneously.

21. A method of fabricating an organic light emitting diode system comprising:
disposing a hole transport layer onto a flexible substrate having a plurality of first electrodes patterned thereon, wherein the hole transport layer is disposed using a web coating process;
patterning the hole transport layer by solvent assisted wiping;
disposing a light emitting polymer layer onto the hole transport layer using the web coating process; and
patterning the light emitting polymer layer by solvent assisted wiping.

22. The method of fabricating an organic light emitting diode system, as set forth in claim 21, wherein disposing the hole transport layer comprises disposing a PEDOT layer.

23. The method of fabricating an organic light emitting diode system, as set forth in claim 21, wherein disposing the hole transport layer comprises disposing a hole transport layer having a thickness variation of less than 10%.

24. The method of fabricating an organic light emitting diode system, as set forth in claim 21, wherein disposing the hole transport layer comprises disposing a layer having a thickness in the range of approximately 0.01 μm to 1.0 μm.

25. The method of fabricating an organic light emitting diode system, as set forth in claim 21, wherein disposing the hole transport layer comprises disposing a the hole transport layer by Micro Gravure™ coating.

26. The method of fabricating an organic light emitting diode system, as set forth in claim 21, wherein disposing the light emitting layer comprises disposing a hole transport layer having a thickness variation of less than 10%.

27. The method of fabricating an organic light emitting diode system, as set forth in claim 21, wherein disposing the light emitting layer comprises disposing a layer having a thickness in the range of approximately 0.01 μm to 1.0 μm.

28. The method of fabricating an organic light emitting diode system, as set forth in claim 21, wherein patterning the hole transport layer and patterning the light emitting polymer layer occur simultaneously.
